(19) United States
(12) Patent Application Publication
(10) Pub. No.: US 2026/0227813 A1
(43) Pub. Date: Aug. 6, 2026

(54) APPARATUS, SYSTEM AND METHODS FOR A TEMPERATURE COMPENSATED CURRENT REFERENCE

(71) Applicant: Microchip Technology Inc., Chandler, AZ (US)

(72) Inventors: Shubham Mehrotra, Morges (CH); Vincent Quiquempoix, Divonne-Les-Bains (FR); Fabien Vaucher, Lausanne (CH)

(73) Assignee: Microchip Technology Inc., Chandler, AZ (US)

(21) Appl. No.: 19/328,941

(22) Filed: Sep. 15, 2025

Related U.S. Application Data
(60) Provisional application No. 63/750,195, filed on Jan. 27, 2025.

(51) Int. Cl. G05F 3/26

(52) U.S. Cl. CPC G05F 3/26

(57) ABSTRACT

An apparatus may include a current mirror circuit, a cascode circuit and a current generator circuit. The current generator circuit may produce a Proportional-to-Absolute Temperature (PTAT) current and a Complementary-to-Absolute Temperature (CTAT) current. The PTAT current and the CTAT current may be based on a first impedance and a second impedance. A combination of the PTAT current and the CTAT current may be a current reference. The values of the first impedance and the second impedance may be chosen to reduce the first-order temperature coefficient of the current reference and the current reference may be a first-order temperature-compensated current reference.

### PRIORITY

This application claims priority to commonly owned United States Provisional Patent Application No. 63/750,195 filed January 27, 2025, the entire contents of which are hereby incorporated by reference for all purposes.

### FIELD OF THE INVENTION

The present disclosure relates to an apparatus, system and method to generate a first-order temperature-compensated current reference.

### BACKGROUND

The current reference circuit is widely used in analog and mixed-signal systems. A current reference may provide a stable bias current for high-precision analog components, including analog-to-digital converters (ADCs), digital-to-analog converters (DACs), amplifiers and precision oscillators.

High-precision analog components may require very stable bias currents over wide operating temperature ranges. Current reference circuits which are susceptible to variation over temperature may impact the performance of those high-precision analog components.

Additionally, low power consumption is a critical performance metric in analog and mixed-signal circuits. Increasing current consumption of the overall solution to improve the operation of a current reference over temperature is not a desirable solution.

There exists a need for current reference circuits which are stable over wide temperature ranges and achieve low overall power consumption.

### SUMMARY

The examples herein enable an apparatus, system and method to generate a first-order temperature-compensated current reference.

According to one aspect, an apparatus includes a current mirror circuit to receive a supply voltage and to output a first current reference and a second current reference. The apparatus includes a cascode circuit to receive as input the first current reference and the second current reference and to output a first cascode output and a second cascode output. The apparatus includes a current generator circuit to receive as input the first cascode output and the second cascode output. A first output of the current generator circuit may be provided to a ground node, a second output of the current generator circuit may be provided to a first impedance. The first impedance may generate a proportional-to-absolute-temperature current and the second cascode output may be provided to a second impedance. The second impedance may generate a complementary-to-absolute-temperature current.

Aspects as in the previous paragraph provide an apparatus, the current mirror circuit comprising a first current mirror device and a second current mirror device. The first current mirror device comprising a first node to receive a supply voltage, a second node communicatively coupled to a second node of the second current mirror device and a third node comprising the first current reference. The second current mirror device comprising a first node to receive a supply voltage, the second node communicatively coupled to the second node of the first current mirror device and a third node coupled to the second node of the second current mirror device, the third node comprising the second current reference.

Aspects as in at least one of the previous two paragraphs provide an apparatus, the cascode circuit comprising a first cascode device and a second cascode device. The first cascode device comprising a first node to receive the first current reference, a second node to receive the first current reference, and a third node comprising the first cascode output. The second cascode device comprising a first node to receive the second current reference, a second node to receive the first current reference and a third node comprising the second cascode output.

Aspects as in at least one of the previous three paragraphs provide an apparatus, the current generator circuit comprising a first current generator device and a second current generator device. The first current generator device comprising a first node to receive the first cascode output, a second node to receive the first cascode output and a third node provided to a ground node. The second current generator device comprising a first node to receive the second cascode output and to provide input to a first node of the second impedance, a second node to receive the first cascode output and a third node to provide input to a first node of the first impedance. A second node of the first impedance is communicatively coupled to a ground node and a second node of the second impedance is communicatively coupled to the ground node.

Aspects as in at least one of the previous four paragraphs provide an apparatus, wherein the size of the second current generator device is an integer multiple of the size of the first current generator device.

Aspects as in at least one of the previous five paragraphs provide an apparatus, wherein the size of the first current mirror device substantially equal to the size of the second current mirror device and the absolute value of the first current reference substantially equal to the absolute value of the second current reference.

Aspects as in at least one of the previous six paragraphs provide an apparatus, wherein the value of the first impedance and the second impedance to produce a first-order temperature-compensated current reference.

Aspects as in at least one of the previous seven paragraphs provide an apparatus, wherein the second current reference comprising a linear combination of the current in the first impedance and the current in the second impedance, the second current reference comprising a temperature-compensated current reference.

Aspects as in at least one of the previous eight paragraphs provide an apparatus, wherein a startup circuit to provide a current to the first node of the first cascode device to initiate a startup operation.

Aspects as in at least one of the previous nine paragraphs provide an apparatus, the cascode circuit comprising a series combination of at least one cascode device in a first leg and at least one cascode device in a second leg.

Aspects provide a system, the system comprising an analog peripheral circuit, the analog peripheral circuit to receive a temperature-compensated current reference. The system includes an apparatus to generate the temperature-compensated current reference, the apparatus comprising: a current mirror circuit to receive a supply voltage and to output a first current reference and a second current reference, a cascode circuit to receive as input the first current reference and the second current reference and to output a first cascode output and a second cascode output, and a current generator circuit to receive as input the first cascode output and the second cascode output. A first output of the current generator circuit to be provided to a ground node, a second output of the current generator circuit to be provided to a first impedance, the first impedance to generate a proportional-to-absolute-temperature current and the second cascode output to be provided to a second impedance, the second impedance to generate a complementary-to-absolute-temperature current.

Aspects as in the previous paragraph provides a system, wherein the value of the first impedance and the second impedance to produce a first-order temperature-compensated current at the second current reference, the second current reference to be mirrored to the analog peripheral. The first and second current mirror devices may have the same size, and a first-order temperature-compensated current may be generated at both the first and second current references, which may be mirrored to an analog peripheral.

Aspects as in at least one of the previous two paragraphs provide a system, wherein the second current reference comprising a linear combination of the current in the first impedance and the current in the second impedance, the second current reference comprising a temperature-compensated current reference and the temperature-compensated current reference to be mirrored to the analog peripheral.

Aspects as in at least one of the previous three paragraphs provide a system, the analog peripheral comprising one of an analog-to-digital converter, a digital-to-analog converter, an oscillator, an amplifier, a comparator, a sensor, a switching regulator, and a power management integrated circuit.

Aspects as in at least one of the previous four paragraphs provide a system, the cascode circuit comprising a series combination of at least one cascode device in a first leg and at least one cascode device in a second leg.

Aspects provide a method, the method comprising: selecting a value of a first impedance, setting a value of a second impedance based on the value of the first impedance and a temperature profile of a current flowing through the first impedance, varying, ratiometrically, the value of the first impedance and the value of the second impedance to generate a desired current value, outputting a temperature-compensated current reference if the temperature coefficient is within a target range, and readjusting the second impedance if the temperature coefficient is not within the target range.

Aspects as in the previous paragraph provides a method, the single leg of the system comprising a current generator device, a first node of the current generator device coupled to the first impedance and a second node of the current generator device coupled to the second impedance.

Aspects as in at least one of the previous two paragraphs provide a method, the value of the first impedance and the value of the second impedance related by a ratio a, the value of a to reduce the temperature dependence of the temperature-compensated current reference.

### BRIEF DESCRIPTION OF THE DRAWINGS

FIG. 1 illustrates one of various examples of an apparatus for generating a first-order temperature-compensated current reference.

FIG. 2 illustrates a system for generating a first-order temperature-compensated current reference.

FIG. 3 illustrates one of various examples of a PTAT current, a CTAT current, and a temperature-compensated current reference.

FIG. 4 illustrates a block diagram of a method for generating a first-order temperature-compensated current reference.

### DETAILED DESCRIPTION

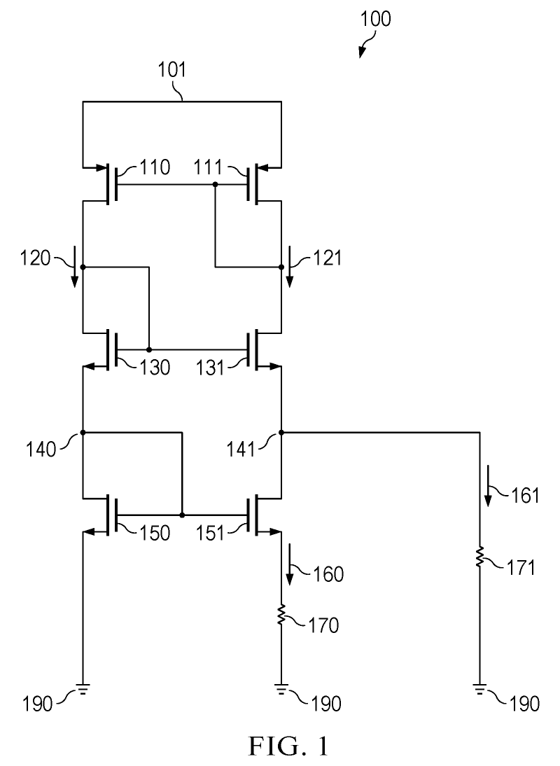

FIG. 1 illustrates one of various examples of an apparatus 100 for generating a first-order temperature-compensated current reference.

Apparatus 100 may include supply 101. Supply 101 may be coupled to a first current mirror device 110 and a second current mirror device 111. First current mirror device 110 and second current mirror device 111 may comprise a current mirror circuit. First current mirror device 110 and second current mirror device 111 may be biased in strong inversion and may have substantially the same size to be well matched in current.

First current mirror device 110 may generate first current reference 120. Second current mirror device 111 may generate second current reference 121. In operation, the current value of first current reference 120 and the current value of the second current reference 121 may, provided the size of first current mirror device 110 is the same as the size of second current mirror device 111, be substantially similar.

A first node of first current mirror device 110 may be coupled to supply 101. A first node of second current mirror device 111 may be coupled to supply 101. Supply 101 may be coupled to a voltage source and may provide a supply voltage to apparatus 100.

A second node of first current mirror device 110 may be coupled to a second node of second current mirror device 111 and to a third node of second current mirror device 111. A third node of first current mirror device 110 may be first current reference 120. The third node of second current mirror device 111 may be second current reference 121.

The third node of first current mirror device 110 may be coupled to a first node of first cascode device 130 and first current reference 120 may be input to first cascode device 130. The third node of second current mirror device 111 may be coupled to a first node of second cascode device 131 and second current reference 121 may be input to second cascode device 131.

A second node of first cascode device 130 may be coupled to a second node of second cascode device 131. The second node of first cascode device 130 may be coupled to the first node of first cascode device 130.

Node 140 may be a first cascode output and may be coupled to a third node of first cascode device 130. Node 141 may be a second cascode output and may be coupled to a third node of second cascode device 131.

First cascode device 130 and second cascode device 131 may comprise a cascode circuit.

A first node of first current generator device 150 may be coupled to node 140. A first node of second current generator device 151 may be coupled to node 141. A second node of first current generator device 150 may be coupled to a second node of second current generator device 151. The second node of first current generator device 150 may be coupled to the first node of first current generator device 150.

In one of various examples, the size of second current generator device 151 may be an integer multiple of the size of first current generator device 150.

A third node of first current generator device 150 may be coupled to ground node 190. A third node of second current generator device 151 may be coupled to a first node of a first impedance 170. A second node of first impedance 170 may be coupled to ground node 190.

The first node of second current generator device 151 may be coupled to a first node of a second impedance 171. The second node of second impedance 171 may be coupled to ground node 190. First current generator device 150 and second current generator device 151 may be biased in weak inversion with an inversion coefficient typically less than 0.1.

Current 160 may be a Proportional-to-Absolute-Temperature (PTAT) current, and may be directly proportional to absolute temperature, such that an increase in temperature results in an increase in current. Current 161 may be a Complementary-to-Absolute-Temperature (CTAT) current, and may be inversely proportional to absolute temperature, such that an increase in absolute temperature results in a decrease in current.

In operation, first cascode device 130 and second cascode device 131 may operate in weak inversion. First cascode device 130 and second cascode device 131 may operate in weak inversion to maximize headroom and facilitate operation over a wider supply range. A voltage at node 140 may be substantially equal to a voltage at node 141. Current 160 through first impedance 170 may be a PTAT current, and current 161 through second impedance 171 may be a CTAT current. Second current reference 121 may be a linear combination of current 160 through first impedance 170 and current 161 through second impedance 171. First current reference 120 may be the same as the second current reference 121, and the current mirrors 110 and 111 may have the size ratio 1:1 or have the same size. In one of various examples, a value of first impedance 170 may be R1, and a value of second impedance 171 may be R2. The value of R2 may be set to be R2=α*R1, where α is selected to reduce the variation in the current value of the second current reference 121 across absolute temperature. The value of α may be chosen to produce a second current reference 121 which is first-order compensated for variations in absolute temperature. After finding α, R1 and R2 may be adjusted ratiometrically to achieve the desired value of the current reference. This may be adjusted at one temperature, as the temperature coefficient (TC) may be already compensated for in previous steps. If, after adjustment, the temperature compensation deviates, α may be readjusted. Then, again, the value of first impedance 170 may be varied from R1 and the value of second impedance 171 may be varied from R2 in a ratiometric manner to restore the desired current. The steps may repeat iteratively, until the desired current and desired temperature compensation is achieved.

Apparatus 100 is illustrated with complimentary metal-oxide semiconductor (CMOS) devices, but this is not intended to be limiting. Apparatus 100 may include bipolar devices or other transistor types not specifically mentioned. As they are generated as part of a current mirror, first current reference 120 and second current reference 121 may be first-order temperature-compensated.

First cascode device 130 may comprise a portion of a first leg of apparatus 100. Second cascode device 131 may comprise a portion of a second leg of apparatus 100.

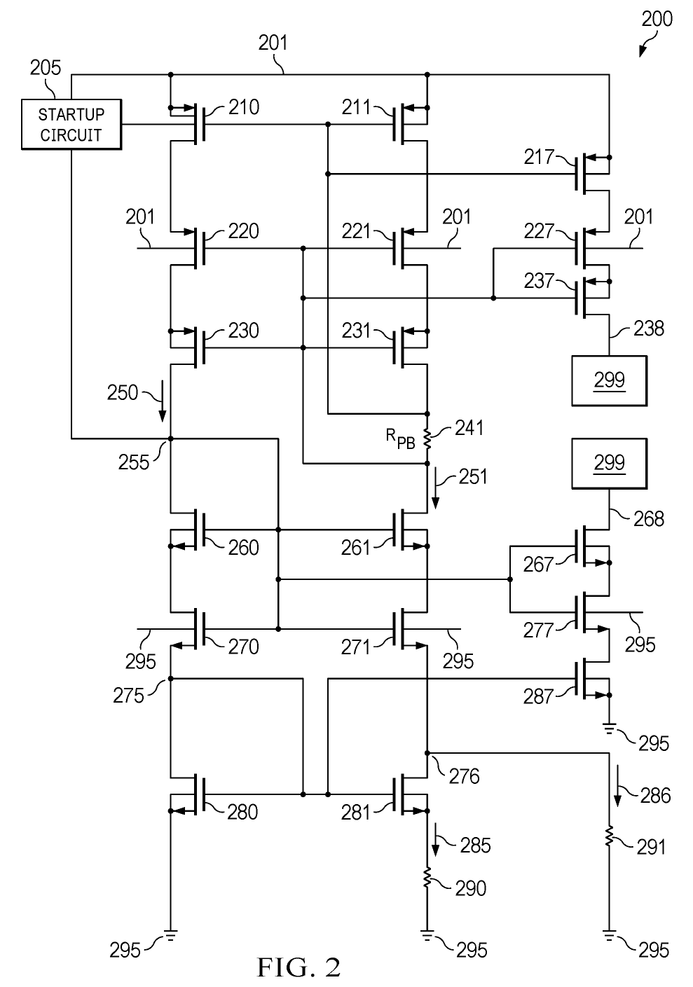

FIG. 2 illustrates a system 200 for generating a first-order temperature-compensated current reference.

System 200 may include supply 201. Supply 201 may be coupled to a first current mirror device 210, to a second current mirror device 211, and to startup circuit 205. A first node of first current mirror device 210 may be coupled to supply 201. A first node of second current mirror device 211 may be coupled to supply 201. Supply 201 may be coupled to a voltage source and may provide a supply voltage to system 200.

First current mirror device 210 and second current mirror device 211 may be biased in strong inversion.

First cascode device 220 and second cascode device 221 may be biased in weak inversion. Third cascode device 230 and fourth cascode device 231 may be biased in weak inversion. Fifth cascode device 260 and sixth cascode device 261 may be biased in weak inversion. Seventh cascode device 270 and eighth cascode device 271 may be biased in weak inversion. First current generator device 280 and second current generator device 281 may be initially biased in weak inversion.

A second node of first current mirror device 210 may be coupled to a second node of second current mirror device 211.

A first node of first cascode device 220 may be coupled to a third node of first current mirror device 210. A first node of second cascode device 221 may be coupled to a third node of second current mirror device 211. A second node of first cascode device 220 may be coupled to a second node of second cascode device 221.

A first node of third cascode device 230 may be coupled to a third node of first cascode device 220. A first node of fourth cascode device 231 may be coupled to a third node of second cascode device 221. A second node of third cascode device 230 may be coupled to a second node of fourth cascode device 231.

A second node of second current mirror device 211 may be coupled to a third node of fourth cascode device 231. A second node of first current mirror device 210 may be coupled to a third node of fourth cascode device 231.

A third node of fourth cascode device 231 may be coupled to a first node of current mirror biasing resistor 241.

A second node of second cascode device 221 may be coupled to a second node of current mirror biasing resistor 241. A second node of first cascode device 220 may be coupled to a second node of current mirror biasing resistor 241.

A second node of fourth cascode device 231 may be coupled to a second node of current mirror biasing resistor 241. A second node of third cascode device 230 may be coupled to a second node of current mirror biasing resistor 241.

First current mirror device 210, second current mirror device 211, first cascode device 220, second cascode device 221, third cascode device 230, fourth cascode device 231 and current mirror biasing resistor 241 may comprise a current mirror circuit.

The value of current mirror biasing resistor 241 depends on the current flowing through current mirror biasing resistor 241. First cascode device 220 and second cascode device 221 may themselves function as a cascode, but to further increase the output impedance, third cascode device 230 and fourth cascode device 231 may be added. The bulk connection of first cascode device 220 and the bulk connection of second cascode device 221 may be connected to supply 201. The bulk connection of third cascode device 230 may be connected to the source node of third cascode device 230. The bulk connection of fourth cascode device 231 may be connected to the source node of fourth cascode device 231. This approach of partitioning the cascode devices may increase the output impedance and preserve headroom.

One node of third cascode device 230 may be coupled to first current reference 250 and one node of fourth cascode device 231 may be coupled to second current reference 251. In operation, the current value of first current reference 250 and the current value of the second current reference 251 may be substantially similar, provided the size of first current mirror device 210 is the same as second current mirror device 211.

Startup circuit 205 may produce a current at node 255, the current from the startup circuit 205 to provide current at node 255 to initiate a startup operation of system 200.

The third node of third cascode device 230 may be coupled to a first node of fifth cascode device 260 and first current reference 250 may be input to fifth cascode device 260. The second node of current mirror biasing resistor 241 may be coupled to a first node of sixth cascode device 261 and second current reference 251 may be input to sixth cascode device 261 via current mirror biasing resistor 241.

A second node of fifth cascode device 260 may be coupled to a second node of sixth cascode device 261. The second node of fifth cascode device 260 may be coupled to the first node of fifth cascode device 260 and may be coupled to an output of startup circuit 205.

A third node of fifth cascode device 260 may be coupled to a first node of seventh cascode device 270. A third node of sixth cascode device 261 may be coupled to a first node of eighth cascode device 271.

A second node of seventh cascode device 270 may be coupled to a second node of eighth cascode device 271. The second node of seventh cascode device 270 may be coupled to the first node of fifth cascode device 260 and may be coupled to an output of startup circuit 205.

Fifth cascode device 260, sixth cascode device 261, seventh cascode device 270 and eighth cascode device 271 may comprise a cascode circuit. Seventh cascode device 270 and eighth cascode device 271 may themselves function as a cascode. To further increase the output impedance, fifth cascode device 260 and sixth cascode device 261 may be added. The bulk connection of fifth cascode device 260 may be coupled to the source node of fifth cascode device 260. The bulk connection of sixth cascode device 261 may be connected to the source node of sixth cascode device 261. The bulk connection of seventh cascode device 270 and the bulk connection of eighth cascode device 271 may be coupled to ground node 295. Fifth cascode device 260 and sixth cascode device 261 may be deep N-well devices. This approach of partitioning the cascode devices may increase the output impedance and preserve headroom.

Node 275 may be a first cascode output and may be coupled to a third node of seventh cascode device 270. Node 276 may be a second cascode output and may be coupled to a third node of eighth cascode device 271.

Node 275 may be coupled to first current generator device 280. Node 276 may be coupled to second current generator device 281. First current generator device 280 and second current generator device 281 may be low-voltage devices which may enable wider supply operation with better matching of threshold voltages.

A first node of first current generator device 280 may be coupled to node 275. A first node of second current generator device 281 may be coupled to node 276. A second node of first current generator device 280 may be coupled to a second node of second current generator device 281. The second node of first current generator device 280 may be coupled to the first node of first current generator device 280.

The third node of first current generator device 280 may be coupled to ground node 295. The third node of second current generator device 281 may be coupled to a first node of a first impedance 290. A second node of first impedance 290 may be coupled to ground node 295.

The first node of second current generator device 281 may be coupled to a first node of a second impedance 291. The second node of second impedance 291 may be coupled to ground node 295.

First current generator device 280 and second current generator device 281 may be initially biased in weak inversion, with an inversion coefficient below 0.1, and current 285 may be a Proportional-to-Absolute-Temperature (PTAT) current, and may be directly proportional to absolute temperature, such that an increase in temperature results in an increase in current. Current 286 may be a Complementary-to-Absolute-Temperature (CTAT) current, and may be inversely proportional to absolute temperature, such that an increase in absolute temperature results in a decrease in current.

The voltage at node 275 may be substantially equal to the voltage at node 276. Current 285 through first impedance 290 may be a PTAT current, and current 286 through second impedance 291 may be a CTAT current. Second current reference 251 may be a linear combination of current 285 through first impedance 290 and current 286 through second impedance 291. In one of various examples, a value of the first impedance may be R1, and a value of the second impedance may be R2. The value of R2 may be set to be R2=α*R1, where α is selected to reduce the variation in the second current reference across absolute temperature. The value of α may be chosen to produce a second current reference 251 which is first-order compensated for variations in absolute temperature. After finding α, R1 and R2 may be adjusted ratiometrically to achieve the desired value of the current reference. This may be performed at one temperature, as the temperature coefficient (TC) is already compensated for in previous steps. If, after adjustment, the temperature compensation changes, α may be readjusted. Then, the value of R1 and R2 may be varied ratiometrically to restore the desired current. The steps may be repeated iteratively until the desired current with the desired temperature compensation is achieved.

A bulk connection of first cascode device 220 may be coupled to supply 201. A bulk connection of second cascode device 221 may be coupled to supply 201. A bulk connection of seventh cascode device 270 may be coupled to a ground node.

A bulk connection of eighth cascode device 271 may be coupled to a ground node. The cascodes may be partitioned by connecting the bulk connection of fifth cascode device 260 to the source node of fifth cascode device 260 and by connecting the bulk connection of sixth cascode device 261 to the source node of sixth cascode device 261. Fifth cascode device 260 and sixth cascode device 261 may be deep n-well devices. A bulk connection of third cascode device 230 may be coupled to the source node of third cascode device 230 rather than to a supply node. A bulk connection of fourth cascode device 231 may be coupled to the source node of fourth cascode device 231 rather than to a supply node. This approach of partitioning the cascode devices may increase the output impedance and preserve headroom. This approach may achieve high PSRR together with temperature compensation at very low power.

System 200 is illustrated with complimentary metal-oxide semiconductor (CMOS) devices, but this is not intended to be limiting. System 200 may include bipolar devices or other transistor types not specifically mentioned.

Second current generator device 281, first impedance 290 and second impedance 291 may comprise one portion of a single leg of system 200.

In one of various examples, the size of second current generator device 281 may be an integer multiple of the size of first current generator device 280. The sizes of first current mirror device 210 and second current mirror device 211 may be substantially the same size.

In one of various examples, the sizes of first current mirror device 210 and second current mirror device 211 may be related by an integer multiple, and the size of second current generator device 281 and the size of first current generator device 280 may be substantially equal.

Devices 217, 227 and 237 may comprise a current mirror and may source reference current 238 to analog peripheral 299. A bulk connection of device 227 may be coupled to supply 201. Devices 267, 277 and 287 may comprise a current mirror and may sink reference current 268 from analog peripheral 299. A bulk connection of device 277 may be coupled to ground node 295.

Analog peripheral 299 may be an analog-to-digital converter (ADC), digital-to-analog converters (DAC), amplifier, precision oscillator, or another analog circuit not specifically mentioned.

As they are generated as part of a current mirror, first current reference 250 and second current reference 251 may be first-order temperature-compensated.

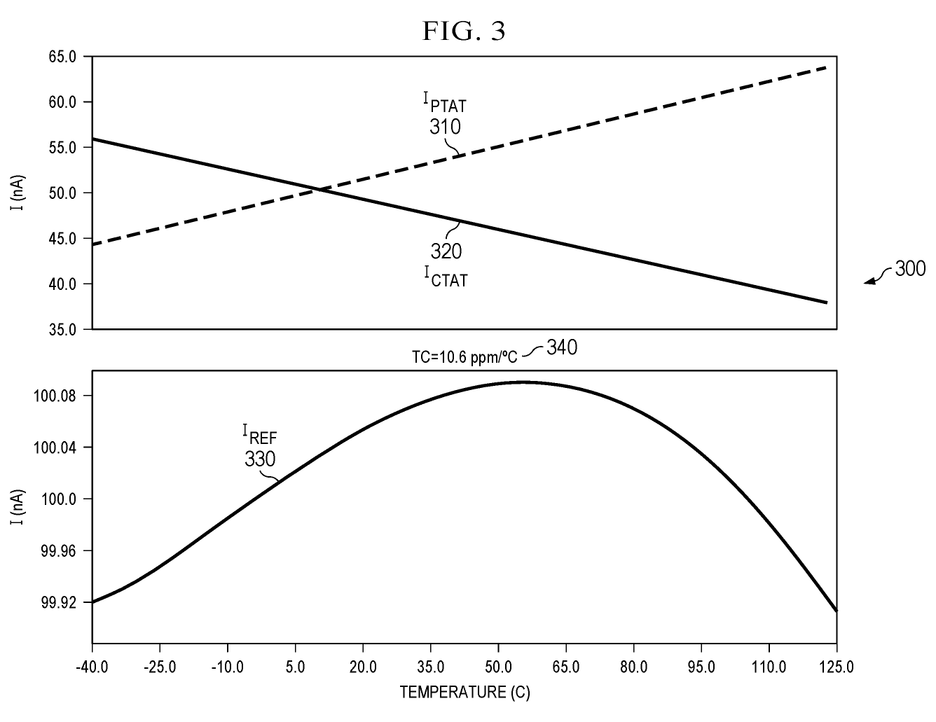

FIG. 3 illustrates one of various examples of a PTAT current, a CTAT current, and a temperature-compensated current reference.

PTAT current 310 may be generated based on current 160 through first impedance 170 as described and illustrated in reference to FIG. 1. PTAT current 310 may be generated based on current 285 through first impedance 290 as described and illustrated in reference to FIG. 2. PTAT current 310 may be directly proportional to absolute temperature, such that the current increases for increasing absolute temperature.

CTAT current 320 may be generated based on current 161 through second impedance 171 as described and illustrated in reference to FIG. 1. CTAT current 320 may be generated based on current 286 through second impedance 291 as described and illustrated in reference to FIG. 2. CTAT current 320 may be inversely proportional to absolute temperature, such that the current decreases for increasing absolute temperature.

Current reference 330 may represent a linear combination of PTAT current 310 and CTAT current 320. Current reference 330 may represent second current reference 121 as described and illustrated in reference to FIG. 1. Current reference 330 may represent second current reference 251 as described and illustrated in reference to FIG. 2. As the sizes of first current mirror device 210 and second current mirror device 211 are substantially the same and operate as a current mirror, current reference 330 may also represent first current reference 250. Temperature coefficient 340 may represent a variation in current reference 330 over absolute temperature. The specific value of temperature coefficient 340 is not intended to be limiting.

The specific temperature ranges, current values, and temperature variation illustrated in FIG. 3 is not intended to be limiting. In other examples, a different temperature range may be represented, a different current value may be represented, and a different temperature variation may be represented.

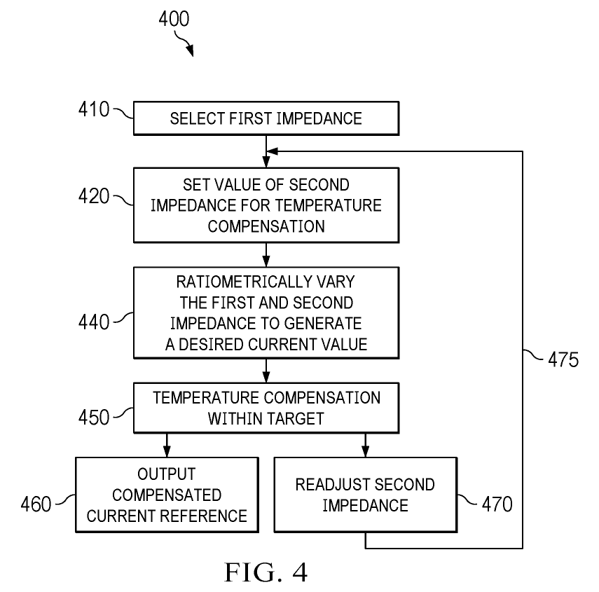

FIG. 4 illustrates a flow chart of a method 400 for generating a temperature-compensated current reference. The method illustrated in FIG. 4 may be a method used to generate a temperature-compensated current reference in an apparatus or system as described and illustrated in reference to FIG. 1 or FIG. 2.

At operation 410, a value of a first impedance may be selected. The first impedance may be first impedance 170 as described and illustrated in reference to FIG. 1. The first impedance may be first impedance 290 as described and illustrated in reference to FIG. 2. The value of the first impedance may be selected based on a desired current value. The value of the first impedance may be selected based on a noise requirement, a voltage requirement, or another circuit requirement not specifically mentioned.

At operation 420, a value of a second impedance may be determined. The second impedance may be second impedance 171 as described and illustrated in reference to FIG. 1. The second impedance may be second impedance 291 as described and illustrated in reference to FIG. 2.

The value of the second impedance may be determined based on the temperature profile of a current flowing through the first impedance, and may be based on the equation R2 =α*R1, where R2 is a value of the second impedance, R1 is a value of the first impedance, and α is a scalar value. α may be selected to reduce the temperature coefficient of a current reference. The current reference may be second current reference 121 as described and illustrated in reference to FIG. 1. The current reference may be the second current reference 251 as described and illustrated in reference to FIG. 2.

In one of various examples, the value of the second impedance may be determined based on an iterative process. An initial value of α may be determined, and a temperature coefficient of a current reference may be determined. The temperature coefficient may be determined based on a circuit simulation or based on measurement of circuit performance. As one of various examples, a value for R1 may be set and a value of α may be set to compensate for the temperature coefficient and to reduce the first-order temperature coefficient of the current reference. Another example may include a variable R1, and a variable R2. Values of R1 and R2 may be swept to test combinations of R1 and R2 to cancel first-order temperature variation.

Based on the temperature coefficient, the value of α may be modified, and the temperature coefficient may be determined for the modified value of α. This process may continue until the temperature coefficient reaches a minimum value or until the temperature coefficient is within an acceptable threshold. In this manner, the value of α may be selected to reduce the temperature dependence of the temperature-compensated current reference.

At operation 440, the first resistor R1 and the second resistor R2 may be varied ratiometrically, keeping the value of α constant, to achieve a desired current reference value.

At operation 450, if the temperature coefficient is within a target range, operation may proceed to operation 460 and the apparatus may output the compensated current reference of desired value.

If, after scaling R1 and R2, the temperature compensation deviates out of the target range, α may be readjusted and the values of R1 and R2 may again be varied ratiometrically to restore the desired current.

If the temperature coefficient is not within the target range, operation may proceed to operation 470 and the second impedance may be readjusted to further optimize the temperature coefficient. The method may proceed via path 475 and operations 450, 460 and 470 may be repeated iteratively until a desired temperature coefficient is achieved for a desired current value.

The method 400 as described and illustrated in reference to FIG. 4 may produce a first-order temperature-compensated current reference.

1. An apparatus comprising:
a current mirror circuit to receive a supply voltage and to output a first current reference and a second current reference;
a cascode circuit to receive as input the first current reference and the second current reference and to output a first cascode output and a second cascode output; and
a current generator circuit to receive as input the first cascode output and the second cascode output, a first output of the current generator circuit to be provided to a ground node, a second output of the current generator circuit to be provided to a first impedance, the first impedance to generate a proportional-to-absolute-temperature current and the second cascode output to be provided to a second impedance, the second impedance to generate a complementary-to-absolute-temperature current.

2. The apparatus as claimed in claim 1, the current mirror circuit comprising a first current mirror device and a second current mirror device, the first current mirror device comprising a first node to receive a supply voltage, a second node communicatively coupled to a second node of the second current mirror device and a third node comprising the first current reference, and the second current mirror device comprising a first node to receive a supply voltage, the second node communicatively coupled to the second node of the first current mirror device and a third node communicatively coupled to the second node of the second current mirror device, the third node comprising the second current reference.

3. The apparatus as claimed in claim 1, the cascode circuit comprising a first cascode device and a second cascode device, the first cascode device comprising a first node to receive the first current reference, a second node to receive the first current reference, and a third node comprising the first cascode output, and the second cascode device comprising a first node to receive the second current reference, a second node to receive the first current reference and a third node comprising the second cascode output.

4. The apparatus as claimed in claim 1, the current generator circuit comprising a first current generator device and a second current generator device, the first current generator device comprising a first node to receive the first cascode output, a second node to receive the first cascode output and a third node provided to a ground node, and the second current generator device comprising a first node to receive the second cascode output and to provide input to a first node of the second impedance, a second node to receive the first cascode output and a third node to provide input to a first node of the first impedance, wherein a second node of the first impedance is communicatively coupled to a ground node and a second node of the second impedance is communicatively coupled to the ground node.

5. The apparatus as claimed in claim 4, wherein the size of the second current generator device is an integer multiple of the size of the first current generator device.

6. The apparatus as claimed in claim 2, the size of the first current mirror device substantially equal to the size of the second current mirror device and the absolute value of the first current reference substantially equal to the absolute value of the second current reference.

7. The apparatus as claimed in claim 1, the value of the first impedance and the second impedance to produce a first-order temperature-compensated current reference.

8. The apparatus as claimed in claim 1, the second current reference comprising a linear combination of the current in the first impedance and the current in the second impedance, the second current reference comprising a temperature-compensated current reference.

9. The apparatus as claimed in claim 3, a startup circuit to provide a current to the first node of the first cascode device to initiate a startup operation.

10. The apparatus as claimed in claim 1, the cascode circuit comprising a series combination of at least one cascode device in a first leg and at least one cascode device in a second leg.

11. A system comprising:
an analog peripheral circuit, the analog peripheral circuit to receive a temperature-compensated current reference;
an apparatus to generate the temperature-compensated current reference, the apparatus comprising:
a current mirror circuit to receive a supply voltage and to output a first current reference and a second current reference;
a cascode circuit to receive as input the first current reference and the second current reference and to output a first cascode output and a second cascode output; and
a current generator circuit to receive as input the first cascode output and the second cascode output, a first output of the current generator circuit to be provided to a ground node, a second output of the current generator circuit to be provided to a first impedance, the first impedance to generate a proportional-to-absolute-temperature current and the second cascode output to be provided to a second impedance, the second impedance to generate a complementary-to-absolute-temperature current.

12. The system as claimed in claim 11, the value of the first impedance and the second impedance to produce a first-order temperature-compensated current at the second current reference, the second current reference to be mirrored to the analog peripheral.

13. The system as claimed in claim 12, the second current reference comprising a linear combination of the current in the first impedance and the current in the second impedance, the second current reference comprising a temperature-compensated current reference and the temperature-compensated current reference to be mirrored to the analog peripheral.

14. The system as claimed in claim 13, the analog peripheral comprising one of an analog-to-digital converter, a digital-to-analog converter, an oscillator, an amplifier, a comparator, a sensor, a switching regulator, and a power management integrated circuit.

15. The system as claimed in claim 13, the cascode circuit comprising a series combination of at least one cascode device in a first leg and at least one cascode device in a second leg.

16. A method comprising:
selecting a value of a first impedance;
setting a value of a second impedance based on the value of the first impedance and a temperature profile of a current flowing through the first impedance;
varying, ratiometrically, the value of the first impedance and the value of the second impedance to generate a desired current value;
outputting a temperature-compensated current reference if the temperature coefficient is within a target range; and
readjusting the second impedance in an iterative manner if the temperature coefficient is not within the target range.

17. The method as claimed in claim 16, the single leg of the system comprising a current generator device, a first node of the current generator device coupled to the first impedance and a second node of the current generator device coupled to the second impedance.

18. The method as claimed in claim 16, the value of the first impedance and the value of the second impedance related by a ratio a, the value of a to reduce the temperature dependence of the temperature-compensated current reference.
